(19) United States
(12) Patent Application Publication
(10) Pub. No.: US 2025/0239835 A1
(43) Pub. Date: Jul. 24, 2025

(54) WAVELENGTH-TUNABLE LIGHT SOURCE DEVICE AND WAVELENGTH CONTROL METHOD

(71) Applicant: NEC Corporation, Minato-ku, Tokyo (JP)

(72) Inventors: Kenji Mizutani, Tokyo (JP); Shigeru Mieda, Tokyo (JP); Naoki Kobayashi, Tokyo (JP); Masaki Oe, Tokyo (JP)

(73) Assignee: NEC Corporation, Minato-ku, Tokyo (JP)

(21) Appl. No.: 18/698,413

(22) PCT Filed: Nov. 11, 2021
(86) PCT No.: PCT/JP2021/041483

§ 371 Date: Apr. 4, 2024

(51) Int. Cl. H01S 5/14

(52) U.S. Cl. CPC H01S 5/141

(57) ABSTRACT

A wavelength-tunable light source device includes an optical amplifier, an optical waveguide provided with a wavelength-tunable filter, a mount on which the optical amplifier and the optical waveguide are mounted and a controller which controls the optical waveguide and the mount, and the controller controls the temperature of the mount such that the wavelength of a ripple caused by internal reflection matches a predetermined wavelength.

### TECHNICAL FIELD

The present invention relates to a wavelength-tunable light source device and a wavelength control method, and particularly, relates to a wavelength-tunable light source device for use in wavelength-division multiplexing communication and a wavelength control method.

### BACKGROUND ART

In recent years, a higher-capacity optical communication system has been desired as an information communication service has become more advanced and diversified. Thus, in an optical communication system, a wavelength-division multiplexing (WDM) scheme that can increase transmission capacity per fiber is employed. Then, in wavelength-division multiplexing (WDM) communication, an optical transceiver including a wavelength-tunable light source that can oscillate at any wavelength among used wavelength bands is used. One example of such a wavelength-tunable light source is described in PTL 1.

In a related wavelength-tunable light source described in PTL 1, a semiconductor optical amplifier is hybrid-mounted on a silicon substrate with integrated optical waveguide devices. The optical waveguide devices include a waveguide type wavelength filter using two ring resonators, a phase adjuster, and a partial reflection mirror. Then, a laser resonator is formed by a path through the semiconductor optical amplifier, the waveguide type wavelength filter, and the partial reflection mirror.

### CITATION LIST

### Patent Literature

PTL 1: Japanese Unexamined Patent Application Publication No. 2019-040099

### SUMMARY OF INVENTION

### Technical Problem

In a wavelength-tunable light source including a semiconductor optical amplifier and an optical waveguide device as in the above-described related wavelength-tunable light source, light passing through two reflection surfaces causes a ripple that is light intensity of transmitted light being increased at a certain period determined by a space between the reflection surfaces. The ripple is caused by reflection inside the optical waveguide device or reflection particularly at a connection between the semiconductor optical amplifier and the optical waveguide device. Thus, in the related wavelength-tunable light source, oscillation may be generated not at a predetermined wavelength 10 but at a ripple wavelength 11 having an increased transmittance, resulting in an unstable oscillation wavelength, as illustrated in FIG. 8.

As described above, the wavelength-tunable light source has a problem of an unstable oscillation wavelength.

An object of the present invention is to provide a wavelength-tunable light source device and a wavelength control method that solve the above-described problem of an unstable oscillation wavelength in a wavelength-tunable light source.

### Solution to Problem

A wavelength-tunable light source device according to the present invention includes: an optical amplification means; an optical waveguide means including a wavelength-tunable filter; a mounting means on which the optical amplification means and the optical waveguide means are mounted; and a control means that controls the optical waveguide means and the mounting means, wherein the control means controls a temperature of the mounting means in such a way that a wavelength of a ripple caused by internal reflection matches a predetermined wavelength.

A wavelength control method according to the present invention includes, when controlling a wavelength of a light source that includes an optical amplification means, an optical waveguide means including a wavelength-tunable filter, and a mounting means on which the optical amplification means and the optical waveguide means are mounted, controlling a temperature of the mounting means in such a way that a wavelength of a ripple caused by internal reflection of the light source matches a predetermined wavelength.

### Advantageous Effects of Invention

A wavelength-tunable light source device and a wavelength control method according to the present invention are able to stabilize an oscillation wavelength of a wavelength-tunable light source.

### BRIEF DESCRIPTION OF DRAWINGS

FIG. 1 is a block diagram illustrating a configuration of a wavelength-tunable light source device according to a first example embodiment of the present invention.

FIG. 2 is a block diagram illustrating a specific configuration of the wavelength-tunable light source device according to the first example embodiment of the present invention.

FIG. 3 is a diagram for describing an operation of a control unit included in the wavelength-tunable light source device according to the first example embodiment of the present invention.

FIG. 4 is a diagram for describing an operation of the control unit included in the wavelength-tunable light source device according to the first example embodiment of the present invention.

FIG. 5 is a diagram illustrating one example of an output characteristic of the wavelength-tunable light source device according to the first example embodiment of the present invention.

FIG. 6 is a block diagram illustrating a configuration of an optical transmission module including the wavelength-tunable light source device according to the first example embodiment of the present invention.

FIG. 7 is a flowchart for describing a wavelength control method according to a second example embodiment of the present invention.

FIG. 8 is a diagram for describing an operation of a related wavelength-tunable light source.

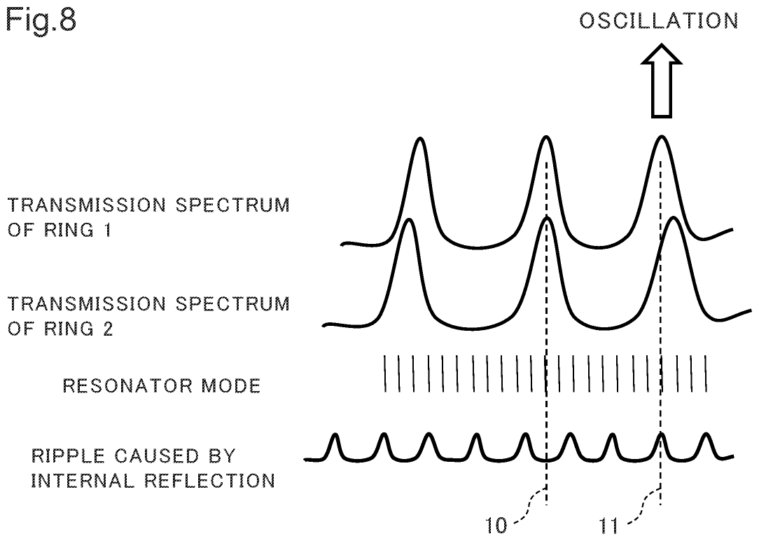

### EXAMPLE EMBODIMENT

Hereinafter, example embodiments of the present invention will be descried with reference to the drawings.

### First Example Embodiment

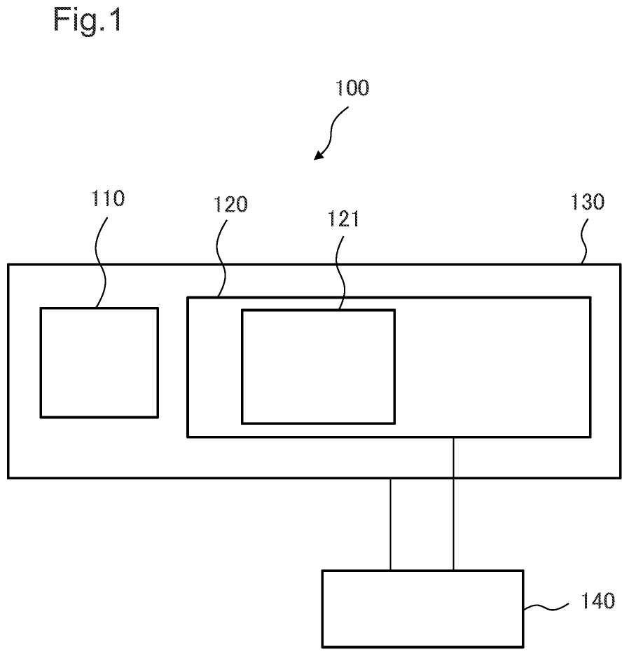

FIG. 1 is a block diagram illustrating a configuration of a wavelength-tunable light source device 100 according to a first example embodiment of the present invention. The wavelength-tunable light source device 100 includes an optical amplification unit (optical amplification means) 110, an optical waveguide unit (optical waveguide means) 120, a mounting unit (mounting means) 130, and a control unit (control means) 140.

The optical waveguide unit 120 includes a wavelength-tunable filter 121. The mounting unit 130 includes the optical amplification unit 110 and the optical waveguide unit 120 mounted thereon. Then, the control unit 140 controls the optical waveguide unit 120 and the mounting unit 130. Herein, the control unit 140 controls a temperature of the mounting unit 130 in such a way that a wavelength of a ripple caused by internal reflection matches a predetermined wavelength.

As described above, in the wavelength-tunable light source device 100 according to the present example embodiment, the control unit 140 is configured to control a temperature of the mounting unit 130 in such a way that a wavelength of a ripple caused by internal reflection matches a predetermined wavelength. Thus, influence on a predetermined oscillation wavelength due to a ripple caused by internal reflection can be avoided. As a result, the wavelength-tunable light source device 100 according to the present example embodiment can stabilize an oscillation wavelength of a wavelength-tunable light source.

Note that, it is difficult to control phase change of waveguide light due to internal reflection by means of refractive index change of a waveguide by previously used heater heating or current injection. However, as described above, the wavelength-tunable light source device 100 according to the present example embodiment is capable of avoiding influence on a predetermined oscillation wavelength due to a ripple caused by internal reflection.

The optical amplification unit (optical amplification means) 110 can be configured to include a semiconductor optical amplifier (SOA). Further, the optical waveguide unit 120 can be configured to include a silicon photonics chip. Then, the wavelength-tunable light source device 100 can be configured to include the semiconductor optical amplifier (SOA) hybrid-mounted with the optical waveguide unit 120. As the mounting unit 130, for example, a silicon substrate can be used.

Herein, the above-described predetermined wavelength is a wavelength for use in wavelength-division multiplexing (WDM) communication, and can be, for example, a wavelength standardized by the International Telecommunication Union (ITU).

The control unit 140 can be further configured to control a refractive index of the wavelength-tunable filter 121 in such a way that a transmission wavelength of the wavelength-tunable filter 121 matches the predetermined wavelength.

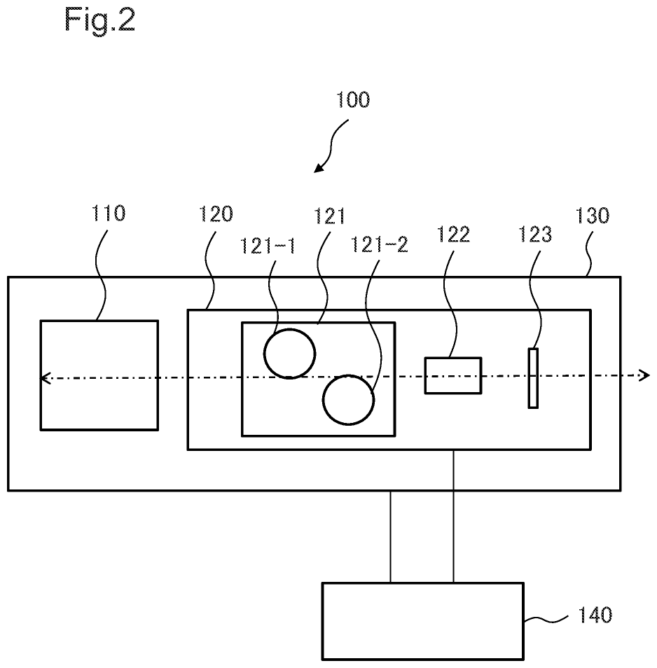

The optical waveguide unit 120 can be configured to include a phase control unit (phase control means) 122 and a partial reflection unit (partial reflection means) 123, as illustrated in FIG. 2. The phase control unit 122 is configured to control a phase of waveguide light propagating the optical waveguide unit 120. Further, the partial reflection unit 123 is configured to reflect a part of the waveguide light. FIG. 2 illustrates a configuration in which the wavelength-tunable filter 121 includes a first ring resonator 121-1 and a second ring resonator 121-2.

A laser resonator is formed by an optical path through the optical amplification unit 110, the wavelength-tunable filter 121, and the partial reflection unit 123, constituting a wavelength-tunable laser. A dashed and single-dotted line in FIG. 2 indicates an optical path of oscillated light of the wavelength-tunable laser.

At this time, the control unit 140 controls a refractive index of the phase control unit 122 in such a way that one of modes of a resonator (external resonator) constituted by the optical amplification unit 110 and the partial reflection unit 123 matches the predetermined wavelength.

Note that, the ripple described above is a peak of light intensity of transmitted light, and is caused by reflection at one end (left end in FIG. 2) of the optical amplification unit 110 and internal reflection. The ripple is generated at a certain period determined by a space between two reflection surfaces. Herein, the internal reflection is reflection in the optical waveguide unit 120 excluding the partial reflection unit 123.

When a semiconductor optical amplifier (SOA) is used as the optical amplification unit 110, a highly reflective-side end face of the semiconductor optical amplifier (SOA) can be the one end of the optical amplification unit 110 described above.

The wavelength-tunable light source device 100 can be configured to further include a first current/voltage application unit (first current/voltage application means), a second current/voltage application unit (second current/voltage application means), and a temperature control unit (temperature control means) (none of the above is illustrated).

Herein, the first current/voltage application unit is configured to control a refractive index of the wavelength-tunable filter 121. The second current/voltage application unit is configured to control a refractive index of the phase control unit 122. As the first current/voltage application unit and the second current/voltage application unit, for example, a heater can be used to heat the wavelength-tunable filter 121 and the phase control unit 122 and thereby control a refractive index of the wavelength-tunable filter 121 and the phase control unit 122.

Without limitation thereto, the first current/voltage application unit and the second current/voltage application unit may be used to apply voltage or inject current to the wavelength-tunable filter 121 and the phase control unit 122 and thereby control a refractive index.

The temperature control unit is configured to either heat or cool the mounting unit 130. As the temperature control unit, typically, a thermoelectric controller (TEC) can be used.

The control unit 140 can be configured to include a storage unit (storage means) that stores a lookup table in which a relationship between first, second, and third control values and the predetermined wavelength is saved. Herein, the first control value is a control value on the first current/voltage application unit for controlling a refractive index of the wavelength-tunable filter 121, and the second control value is a control value on the second current/voltage application unit for controlling a refractive index of the phase control unit 122. Then, the third control value is a control value on the temperature control unit for controlling a temperature of the mounting unit 130.

At this time, the control unit 140 controls a refractive index of the wavelength-tunable filter 121 by controlling the first current/voltage application unit by using the first control value. Further, the control unit 140 controls a refractive index of the phase control unit 122 by controlling the second current/voltage application unit by using the second control value. Then, the control unit 140 controls a temperature of the mounting unit 130 by controlling the temperature control unit by using the third control value.

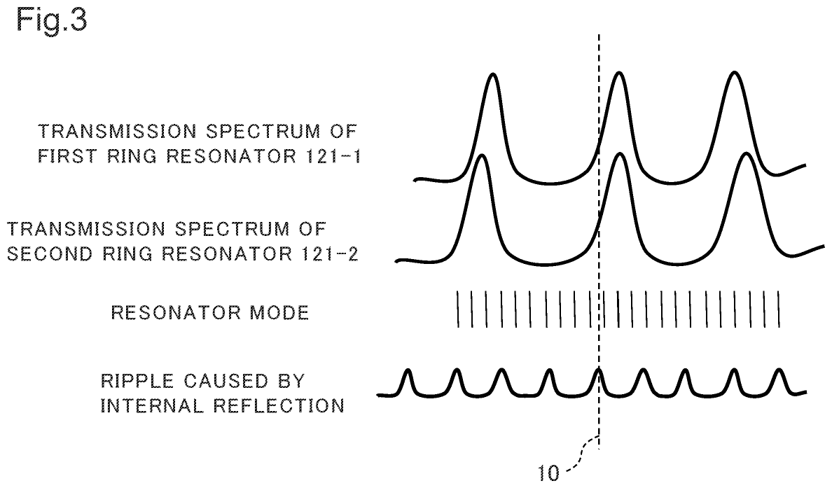

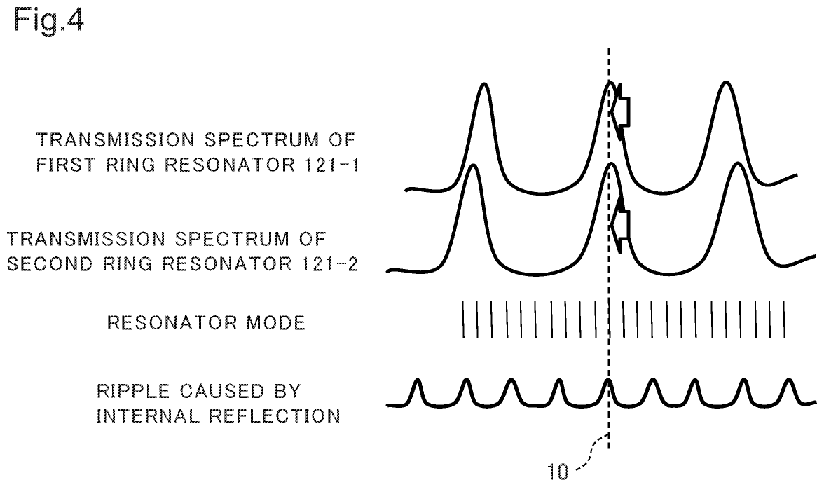

Next, an operation of the control unit 140 will be described in more detail by using FIGS. 3 and 4.

FIGS. 3 and 4 illustrate, from top, transmission spectra of the first ring resonator 121-1 and the second ring resonator 121-2 constituting the wavelength-tunable filter 121, a mode of a resonator constituted by the optical amplification unit 110 and the partial reflection unit 123, and a periodic peak (ripple) of transmitted light intensity caused by internal reflection. A dashed line is an oscillation wavelength of the wavelength-tunable light source device 100, and is a targeted predetermined wavelength 10.

The control unit 140 first controls a temperature of the mounting unit 130 in such a way that a wavelength of a ripple caused by internal reflection matches the predetermined wavelength 10, as illustrated in FIG. 3. Specifically, the control unit 140 controls a temperature of the mounting unit 130 by controlling, for example, a thermoelectric controller (TEC) as the temperature control unit. At this time, a whole of the spectra illustrated in FIG. 3 is shifted.

In view of the above, the control unit 140 controls a refractive index of the first ring resonator 121-1 and the second ring resonator 121-2 constituting the wavelength-tunable filter 121 in such a way that a transmission wavelength of the first ring resonator 121-1 and the second ring resonator 121-2 matches the predetermined wavelength 10, as illustrated in FIG. 4. Specifically, the control unit 140 controls a heater as the first current/voltage application unit, thereby varying a temperature of each of the first ring resonator 121-1 and the second ring resonator 121-2 and controlling a refractive index.

Furthermore, the control unit 140 controls a refractive index of the phase control unit 122 in such a way that one of modes of a resonator constituted by the optical amplification unit 110 and the partial reflection unit 123 matches the predetermined wavelength 10. Specifically, the control unit 140 controls a heater as the second current/voltage application unit, thereby varying a temperature of the phase control unit 122 and controlling a refractive index. Without limitation thereto, current may be injected to the phase control unit 122, thereby controlling a refractive index of the phase control unit 122.

With the control unit 140 performing the above-described control, the wavelength-tunable light source device 100 becomes capable of stably oscillating, for example, at the predetermined wavelength 10 being a wavelength standardized by the International Telecommunication Union

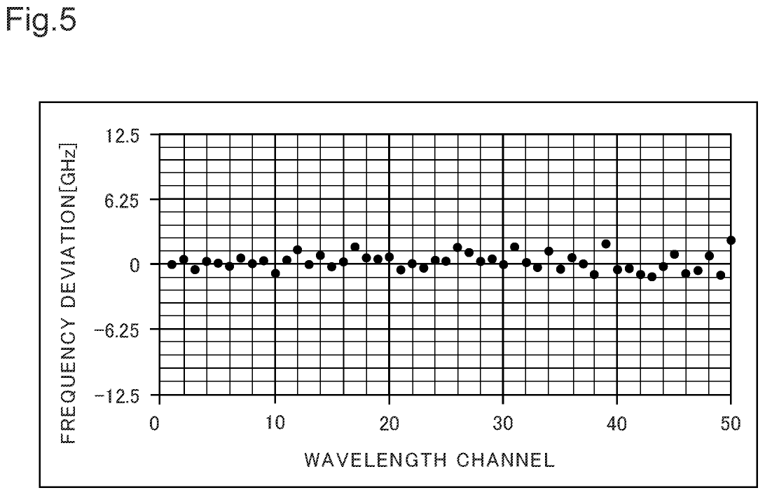

(ITU). With the control unit 140 performing such control for each of all wavelength channels standardized by the International Telecommunication Union (ITU), the wavelength-tunable light source device 100 is capable of performing laser oscillation with high wavelength accuracy over a wide bandwidth. FIG. 5 illustrates one example of an output characteristic of the wavelength-tunable light source device 100. As is clear from the figure, the wavelength-tunable light source device 100 according to the present example embodiment can achieve stable laser oscillation with small frequency deviation in all wavelength channels.

The control unit 140 may employe, as the predetermined wavelength, all wavelength channels standardized by the ITU, and may save, in a lookup table, the first, second, and third control values associated with each wavelength channel. This makes it possible to achieve stable laser oscillation at any wavelength among all wavelength channels. Note that, as the first, second, and third control values, a best condition selected from among a plurality of temperature conditions may be stored in a lookup table.

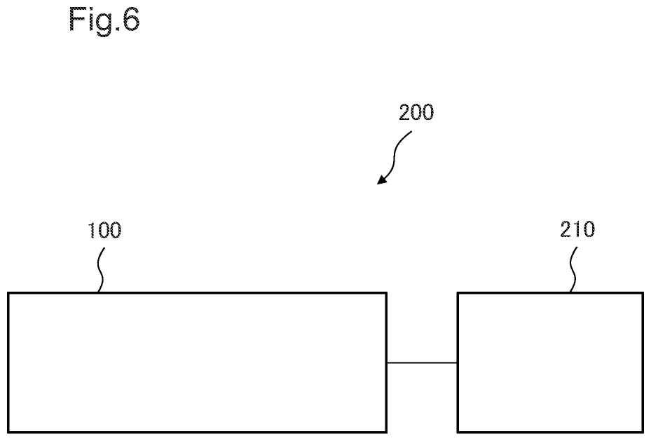

FIG. 6 illustrates a configuration of an optical transmission module 200 including the wavelength-tunable light source device 100 described above. The optical transmission module 200 includes the wavelength-tunable light source device 100 and an optical modulation device 210. The optical modulation device 210 modulates output light of the wavelength-tunable light source device 100. As the optical modulation device 210, typically, a Mach-Zehnder modulator can be used. Since the wavelength-tunable light source device 100 described above is used, the optical transmission module 200 can stabilize an oscillation wavelength of a wavelength-tunable light source.

As described above, the wavelength-tunable light source device 100 according to the present example embodiment can stabilize an oscillation wavelength of a wavelength-tunable light source.

### Second Example Embodiment

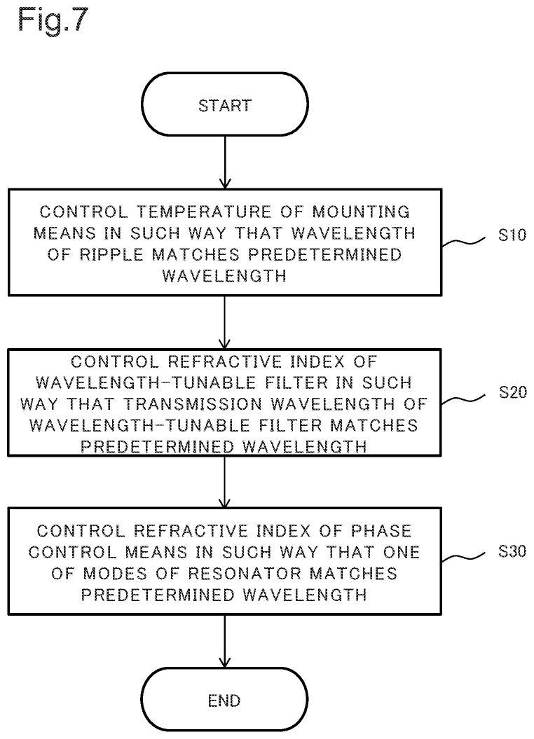

Next, a second example embodiment of the present invention will be described. FIG. 7 illustrates a flowchart for describing a wavelength control method according to the present example embodiment.

The wavelength control method according to the present example embodiment is used in controlling a wavelength of a light source that includes an optical amplification means, an optical waveguide means including a wavelength-tunable filter, and a mounting means on which the optical amplification means and the optical waveguide means are mounted. Herein, the optical amplification means can include a semiconductor optical amplifier, and the optical waveguide means can include a silicon photonics chip.

In the wavelength control method according to the present example embodiment, first, a temperature of the mounting means is controlled in such a way that a wavelength of a ripple caused by internal reflection of the light source matches a predetermined wavelength (Step S10). Thereby, influence on a predetermined oscillation wavelength due to a ripple caused by internal reflection can be avoided. Thus, the wavelength control method according to the present example embodiment can stabilize an oscillation wavelength of a wavelength-tunable light source.

Consequently, a refractive index of the wavelength-tunable filter is controlled in such a way that a transmission wavelength of the wavelength-tunable filter matches the predetermined wavelength (Step S20).

Herein, the optical waveguide means included in the above-described light source can be configured to further include a phase control means and a partial reflection means. The phase control means is configured to control a phase of waveguide light propagating the optical waveguide means. Further, the partial reflection means is configured to reflect a part of the waveguide light. At this time, in the wavelength control method according to the present example embodiment, a refractive index of the phase control means is controlled in such a way that one of modes of a resonator constituted by the optical amplification means and the partial reflection means matches the predetermined wavelength (Step S30).

Note that, the ripple described above is a peak of light intensity of transmitted light, and is caused by reflection at one end of the optical amplification means and reflection in the optical waveguide means excluding the partial reflection means.

The light source described above can be configured to further include a first current/voltage application means, a second current/voltage application means, and a temperature control means. Herein, the first current/voltage application means is configured to control a refractive index of the wavelength-tunable filter. The second current/voltage application means is configured to control a refractive index of the phase control means. Then, the temperature control means is configured to control either heat or cool the mounting means.

In this case, in the wavelength control method according to the present example embodiment, a temperature of the mounting means can be controlled by controlling the temperature control means by using a third control value in Step S10. Further, a refractive index of the wavelength-tunable filter can be controlled by controlling the first current/voltage application means by using a first control value in Step S20. Then, a refractive index of the phase control means can be controlled by controlling the second current/voltage application means by using a second control value in Step S30.

At this time, in the wavelength control method according to the present example embodiment, a lookup table in which a relationship between the first, second, and third control values described above and the predetermined wavelength is saved may be referred to.

Next, a specific example of a control flow using the wavelength control method according to the present example embodiment will be described.

First, in a first stage, a condition stored in a lookup table (LUT) is set in a wavelength-tunable light source device to oscillate. At this time, a wavelength-tunable light source is covered with a shutter or the like in such a way that no light is output externally. However, light output is monitored by using a photodetector (PD) included inside the wavelength-tunable light source device.

In a second stage, wavelength locking control is performed. Herein, only wavelength filter control is performed. Simultaneously, phase control is also performed in such a way that output is always maximized.

Next, in a third stage, a temperature of the mounting means is controlled in such a way that a wavelength of a ripple caused by internal reflection matches a predetermined wavelength (Step S10 in FIG. 7). Then, the temperature is slightly changed, the condition is matched through the control similar to the second stage (Steps S20 and S30 in FIG. 7), and light output is then checked. Furthermore, the temperature is slightly changed and the control is repeated. Then, the wavelength-tunable light source is used by using a temperature condition with highest light output.

Note that, laser may be output after the control in the third stage is finished, or laser may be output at a point in time of the control in the second stage and power may be checked while the temperature is changed at a low frequency in the third stage.

As described above, the wavelength control method according to the present example embodiment can stabilize an oscillation wavelength of a wavelength-tunable light source.

The whole or part of the example embodiments described above can be described as, but not limited to, the following supplementary notes.

(Supplementary note 1) A wavelength-tunable light source device including: an optical amplification means; an optical waveguide means including a wavelength-tunable filter; a mounting means on which the optical amplification means and the optical waveguide means are mounted; and a control means for controlling the optical waveguide means and the mounting means, wherein the control means controls a temperature of the mounting means in such a way that a wavelength of a ripple caused by internal reflection matches a predetermined wavelength.

(Supplementary note 2) The wavelength-tunable light source device according to supplementary note 1, wherein the control means controls a refractive index of the wavelength-tunable filter in such a way that a transmission wavelength of the wavelength-tunable filter matches the predetermined wavelength.

(Supplementary note 3) The wavelength-tunable light source device according to supplementary note 2, wherein the optical waveguide means further includes: a phase control means for controlling a phase of waveguide light propagating the optical waveguide means; and a partial reflection means for reflecting a part of the waveguide light, and the control means controls a refractive index of the phase control means in such a way that one of modes of a resonator constituted of the optical amplification means and the partial reflection means matches the predetermined wavelength.

(Supplementary note 4) The wavelength-tunable light source device according to supplementary note 3, wherein the ripple is a peak of light intensity of transmitted light caused by reflection at one end of the optical amplification means and reflection in the optical waveguide means excluding the partial reflection means.

(Supplementary note 5) The wavelength-tunable light source device according to supplementary note 3 or 4, further including: a first current/voltage application means for controlling a refractive index of the wavelength-tunable filter; a second current/voltage application means for controlling a refractive index of the phase control means; and a temperature control means for either heating or cooling the mounting means, wherein the control means controls a refractive index of the wavelength-tunable filter by controlling the first current/voltage application means by using a first control value, controls a refractive index of the phase control means by controlling the second current/voltage application means by using a second control value, and controls a temperature of the mounting means by controlling the temperature control means by using a third control value.

(Supplementary note 6) The wavelength-tunable light source device according to supplementary note 5, wherein the control means includes a storage means for storing a lookup table in which a relationship between the first, second, and third control values and the predetermined wavelength is saved.

(Supplementary note 7) The wavelength-tunable light source device according to any one of supplementary notes 1 to 6, wherein the optical amplification means includes a semiconductor optical amplifier, and the optical waveguide means includes a silicon photonics chip.

(Supplementary note 8) An optical transmission module including: the wavelength-tunable light source device according to any one of supplementary notes 1 to 7; and an optical modulation device that modulates output light of the wavelength-tunable light source device.

(Supplementary note 9) A wavelength control method including, when controlling a wavelength of a light source that includes an optical amplification means, an optical waveguide means including a wavelength-tunable filter, and a mounting means on which the optical amplification means and the optical waveguide means are mounted, controlling a temperature of the mounting means in such a way that a wavelength of a ripple caused by internal reflection of the light source matches a predetermined wavelength.

(Supplementary note 10) The wavelength control method according to supplementary note 9, wherein the controlling a wavelength of the light source includes controlling a refractive index of the wavelength-tunable filter in such a way that a transmission wavelength of the wavelength-tunable filter matches the predetermined wavelength.

(Supplementary note 11) The wavelength control method according to supplementary note 10, wherein the optical waveguide means further includes: a phase control means for controlling a phase of waveguide light propagating the optical waveguide means; and a partial reflection means for reflecting a part of the waveguide light, and the controlling a wavelength of the light source includes controlling a refractive index of the phase control means in such a way that one of modes of a resonator constituted of the optical amplification means and the partial reflection means matches the predetermined wavelength.

(Supplementary note 12) The wavelength control method according to supplementary note 11, wherein the ripple is a peak of light intensity of transmitted light caused by reflection at one end of the optical amplification means and reflection in the optical waveguide means excluding the partial reflection means.

(Supplementary note 13) The wavelength control method according to supplementary note 11 or 12, wherein the light source further includes: a first current/voltage application means for controlling a refractive index of the wavelength-tunable filter; a second current/voltage application means for controlling a refractive index of the phase control means; and a temperature control means for either heating or cooling the mounting means, and the controlling a wavelength of the light source includes: controlling a refractive index of the wavelength-tunable filter by controlling the first current/voltage application means by using a first control value; controlling a refractive index of the phase control means by controlling the second current/voltage application means by using a second control value; and controlling a temperature of the mounting means by controlling the temperature control means by using a third control value.

(Supplementary note 14) The wavelength control method according to supplementary note 13, wherein the controlling a wavelength of the light source includes referring to a lookup table in which a relationship between the first, second, and third control values and the predetermined wavelength is saved.

(Supplementary note 15) The wavelength control method according to any one of supplementary notes 9 to 14, wherein the optical amplification means includes a semiconductor optical amplifier, and the optical waveguide means includes a silicon photonics chip.

While the invention has been particularly shown and described with reference to exemplary embodiments thereof, the invention is not limited to these embodiments. It will be understood by those of ordinary skill in the art that various changes in form and details may be made therein without departing from the spirit and scope of the present invention as defined by the claims.

### REFERENCE SIGNS LIST

100 Wavelength-tunable light source device
110 Optical amplification unit
120 Optical waveguide unit
121 Wavelength-tunable filter
121-1 First ring resonator
121-2 Second ring resonator
122 Phase control unit
123 Partial reflection unit
130 Mounting unit
140 Control unit
200 Optical transmission module
210 Optical modulation device
10 Predetermined wavelength
11 Ripple wavelength

What is claimed is:

1. A wavelength-tunable light source device comprising:
an optical amplifier;
an optical waveguide including a wavelength-tunable filter;
a mount on which the optical amplifier and the optical waveguide are mounted; and
a controller configured to control the optical waveguide and the mount, wherein
the controller controls a temperature of the mount in such a way that a wavelength of a ripple caused by internal reflection matches a predetermined wavelength.

2. The wavelength-tunable light source device according to claim 1, wherein
the controller controls a refractive index of the wavelength-tunable filter in such a way that a transmission wavelength of the wavelength-tunable filter matches the predetermined wavelength.

3. The wavelength-tunable light source device according to claim 2, wherein
the optical waveguide further includes:
a phase controller configured to control a phase of waveguide light propagating the optical waveguide; and
a partial reflector configured to reflect a part of the waveguide light, and
the controller controls a refractive index of the phase controller in such a way that one of modes of a resonator constituted of the optical amplifier and the partial reflector matches the predetermined wavelength.

4. The wavelength-tunable light source device according to claim 3, wherein
the ripple is a peak of light intensity of transmitted light caused by reflection at one end of the optical amplifier and reflection in the optical waveguide excluding the partial reflector.

5. The wavelength-tunable light source device according to claim 3, further comprising:
a first current/voltage application circuit configured to control a refractive index of the wavelength-tunable filter;
a second current/voltage application circuit configured to control a refractive index of the phase controller; and
a temperature controller configured to either heat or cool the mount, wherein
the controller
controls a refractive index of the wavelength-tunable filter by controlling the first current/voltage application circuit using a first control value,
controls a refractive index of the phase controller by controlling the second current/voltage application circuit using a second control value, and
controls a temperature of the mount by controlling the temperature controller using a third control value.

6. The wavelength-tunable light source device according to claim 5, wherein
the controller includes a storage configured to store a lookup table in which a relationship between the first, second, and third control values and the predetermined wavelength is saved.

7. The wavelength-tunable light source device according to claim 1, wherein
the optical amplifier includes a semiconductor optical amplifier, and
the optical waveguide includes a silicon photonics chip.

8. An optical transmission module comprising:
a wavelength-tunable light source device; and
an optical modulation device that modulates output light of the wavelength-tunable light source device, wherein
the wavelength-tunable light source device includes
an optical amplifier,
an optical waveguide including a wavelength-tunable filter,
amount on which the optical amplifier and the optical waveguide are mounted, and
a controller configured to control the optical waveguide and the mount, wherein
the controller controls a temperature of the mount in such a way that a wavelength of a ripple caused by internal reflection matches a predetermined wavelength.

9. A wavelength control method comprising,
when controlling a wavelength of a light source that includes an optical amplifier, an optical waveguide including a wavelength-tunable filter, and a mount on which the optical amplifier and the optical waveguide are mounted,
controlling a temperature of the mount in such a way that a wavelength of a ripple caused by internal reflection of the light source matches a predetermined wavelength.

10. The wavelength control method according to claim 9, wherein
the controlling a wavelength of the light source includes controlling a refractive index of the wavelength-tunable filter in such a way that a transmission wavelength of the wavelength-tunable filter matches the predetermined wavelength.

11. The wavelength control method according to claim 10, wherein
the optical waveguide further includes:
a phase controller configured to control a phase of waveguide light propagating the optical waveguide; and
a partial reflector configured to reflect a part of the waveguide light, and
the controlling a wavelength of the light source includes controlling a refractive index of the phase controller in such a way that one of modes of a resonator constituted of the optical amplifier and the partial reflector matches the predetermined wavelength.

12. The wavelength control method according to claim 11, wherein
the ripple is a peak of light intensity of transmitted light caused by reflection at one end of the optical amplifier and reflection in the optical waveguide excluding the partial reflector.

13. The wavelength control method according to claim 11, wherein
the light source further includes:
a first current/voltage application circuit configured to control a refractive index of the wavelength-tunable filter;
a second current/voltage application circuit configured to control a refractive index of the phase controller; and
a temperature controller configured to either heat or cool the mount, and
the controlling a wavelength of the light source includes:
controlling a refractive index of the wavelength-tunable filter by controlling the first current/voltage application circuit using a first control value;
controlling a refractive index of the phase controller by controlling the second current/voltage application circuit using a second control value; and
controlling a temperature of the mount by controlling the temperature controller using a third control value.

14. The wavelength control method according to claim 13, wherein
the controlling a wavelength of the light source includes referring to a lookup table in which a relationship between the first, second, and third control values and the predetermined wavelength is saved.

15. The wavelength control method according to claim 9, wherein
the optical amplifier includes a semiconductor optical amplifier, and
the optical waveguide includes a silicon photonics chip.
